(19) United States
(12) Patent Application Publication
(10) Pub. No.: US 2023/0096381 A1
(43) Pub. Date: Mar. 30, 2023

(54) SEMICONDUCTOR DEVICE AND METHOD FOR MANUFACTURING SEMICONDUCTOR DEVICE

(71) Applicant: Fuji Electric Co., Ltd., Kanagawa (JP)

(72) Inventor: Hiroaki ICHIKAWA, Nagano (JP)

(73) Assignee: Fuji Electric Co., Ltd., Kanagawa (JP)

(21) Appl. No.: 17/878,800

(22) Filed: Aug. 1, 2022

(30) Foreign Application Priority Data
Sep. 27, 2021 (JP) 2021-156436

(51) Int. Cl. H01L 23/367; H01L 23/047; H01L 23/373; H01L 23/00; H01L 25/07; H01L 25/18; H01L 21/48

(52) U.S. Cl. CPC H01L 23/367; H01L 23/047; H01L 23/3735; H01L 24/32; H01L 24/48; H01L 24/73; H01L 25/072; H01L 25/18; H01L 21/4807; H01L 21/4817; H01L 21/4871; H01L 2224/32225; H01L 2224/48139; H01L 2224/73265; H01L 2924/12031; H01L 2924/12032; H01L 2924/12036; H01L 2924/13055; H01L 2924/13091

(57) ABSTRACT

A semiconductor device includes: an electrically conductive plate; a semiconductor chip on the electrically conductive plate, the semiconductor chip having a front main electrode on a front surface thereof and a back main electrode on a back surface thereof, the back main electrode being bonded to the electrically conductive plate; and a heat radiating member that is bonded to the front main electrode via a conductive adhesive.

### BACKGROUND OF THE INVENTION

### Technical Field

The present invention relates to a semiconductor device and a method for manufacturing the semiconductor device.

### Background Art

The semiconductor device includes a power device and is used as a power conversion device. Power devices include semiconductor chips. The semiconductor chip is, for example, an IGBT (Insulated Gate Bipolar Transistor) or a power MOSFET (Metal Oxide Semiconductor Field Effect Transistor). Such a semiconductor device includes at least a semiconductor chip, an insulating circuit board on which the semiconductor chip is arranged, and a base substrate on which the insulating circuit board is arranged. The insulating circuit board includes an insulating plate and a circuit pattern arranged on the insulating plate. The semiconductor chip is joined to the circuit pattern by a joining member (for example, solder). The semiconductor device includes a case for accommodating the semiconductor chip and a sealing member for sealing the inside of the case. The case is placed on the base substrate and surrounds the insulating circuit board on which the semiconductor chips are placed. In addition, the case is integrally molded with external connection terminals. Inside the case, the external connection terminal, the circuit pattern of the insulating circuit board, and the main electrode on the front surface of the semiconductor chip are directly connected by wires as appropriate.

### RELATED ART DOCUMENT

### Patent Document

Patent Document 1: Japanese Patent Application Laid-Open Publication No. 2017-17109

### SUMMARY OF THE INVENTION

In the above-mentioned semiconductor device, a large current may flow in a short period of time in the semiconductor chip at the time of abnormality for example. When a large current flows in a short period of time, the electrode (main electrode) on the front surface of the semiconductor chip is heated, and the wires bonded to the front surface may be broken. In addition, rapid heating of the main electrode of the semiconductor chip may lead to failure of the semiconductor chip. When the wire is broken or the semiconductor chip fails, the semiconductor device does not operate normally, lowering the reliability.

The present invention has been made in view of these considerations, and an object of the present invention is to provide a semiconductor device and a method for manufacturing the semiconductor device, which can suppress the occurrence of failure due to heating.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device including: an electrically conductive plate; a semiconductor chip on the electrically conductive plate, the semiconductor chip having a front main electrode on a front surface thereof and a back main electrode on a back surface thereof, the back main electrode being bonded to the electrically conductive plate; and a heat radiating member that is bonded to the front main electrode via a conductive adhesive.

In another aspect, the present disclosure provides a method for manufacturing a semiconductor device, including: a preparation process for preparing an electrically conductive plate, a semiconductor chip having a front main electrode on a front surface thereof and a back main electrode on a back surface thereof, and a heat radiating member; a first bonding step of bonding the back main electrode on the electrically conductive plate so as to mount the semiconductor chip on the electrically conductive plate; and a second bonding step of bonding the heat radiating member to the front main electrode of the semiconductor chip via a conductive adhesive.

In another aspect, the present disclosure provides a semiconductor device, comprising: an electrically conductive plate; a diode chip that includes a semiconductor diode element on the electrically conductive plate, the diode chip having a front main electrode on a front surface thereof and a back main electrode on a back surface thereof, the back main electrode being bonded to the electrically conductive plate, the front main electrode occupying a substantially entirety of the front surface except for an outer peripheral portion of the front surface; an electrically conductive heat radiating member that is bonded to the front main electrode of the diode chip via an electrically and thermally conductive adhesive, the electrically conductive heat radiating member covering a substantially entirety of the front main electrode; a switching element chip that includes a semiconductor switching element on the electrically conductive plate, the switching element chip having a control electrode and a front main electrode on a front surface thereof and a back main electrode on a back surface thereof, the back main electrode being bonded to the electrically conductive plate, the front main electrode occupying a substantially entirety of the front surface except for an outer peripheral portion of the front surface and a region where the control electrode is provided, an area of the front surface of the switching element chip being larger than an area of the front surface of the diode chip; another electrically conductive heat radiating member that is bonded to the front main electrode of the switching element chip via said electrically and thermally conductive adhesive, an area of the another heat radiating member on the front main electrode of the switching element chip being greater than or the same as an area of the heat radiating member on the front main electrode of the diode chip; and one or more of lead wires that are wire-bonded to respective front surfaces of the electrically conductive heat radiating member and the another electrically conductive heat radiating member so that the lead wires provide current paths to the diode chip and the switching element chip through the electrically conductive heat radiating member and the another electrically conductive heat radiating member, respectively, wherein a resistance value of the electrically and thermally conductive adhesive is 1.5×10⁻² Ω·m or less, and a thermal conductivity of the electrically and thermally conductive adhesive is 5 W/m·k or more.

The semiconductor device having the above configuration and the method for manufacturing the semiconductor device suppress the occurrence of failure due to heating and suppress the deterioration of reliability.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view of a semiconductor device according to an embodiment.

FIG. 2 is an enlarged cross-sectional view of a main part of the semiconductor device of the embodiment.

FIG. 3 is a plan view of the semiconductor device of the embodiment.

FIGS. 4A-4B are diagrams (No. 1) for explaining a heat radiating member arranged on the semiconductor chip of an embodiment.

FIG. 5 is a diagram (No. 2) for explaining a heat radiating member arranged on the semiconductor chip of an embodiment.

FIGS. 6A-6B are diagrams (No. 3) for explaining a heat radiating member arranged on the semiconductor chip of an embodiment.

FIGS. 7A-7B are diagrams (No. 4) for explaining a heat radiating member arranged on the semiconductor chip of an embodiment.

FIG. 8 is a flowchart showing a manufacturing method of the semiconductor device according to an embodiment.

FIG. 9 is a diagram for explaining a semiconductor chip of a reference example.

FIGS. 10A-10B are diagrams for explaining a heat radiating member arranged on the semiconductor chip of an embodiment.

### DETAILED DESCRIPTION OF EMBODIMENTS

Hereinafter, embodiments will be described with reference to the drawings. In the following descriptions, the “front surface” and the “upper surface” represent the XY planes facing the upper side (+Z direction) in the semiconductor device shown in the figure. Similarly, “top” represents the direction of the upper side (+Z direction) in the semiconductor device shown in the figure. The “back surface” and the “bottom surface” represent the XY planes facing the lower side (−Z direction) in the semiconductor device shown in the figure. Similarly, “bottom” represents the direction toward the bottom (−Z direction) in the semiconductor device shown in the figure. Other drawings mean the same direction as needed. The “front surface”, “upper surface”, “upper”, “back surface”, “lower surface”, “lower”, and “side surface” are merely expedient expressions for specifying the relative positional relationship, and do not limit the technical idea of the present invention. For example, “top” and “bottom” do not necessarily mean vertical to the ground. That is, the “up” and “down” directions are not limited to the direction of gravity. Further, in the following descriptions, a “main component” means that the component occupies 80 vol % or more.

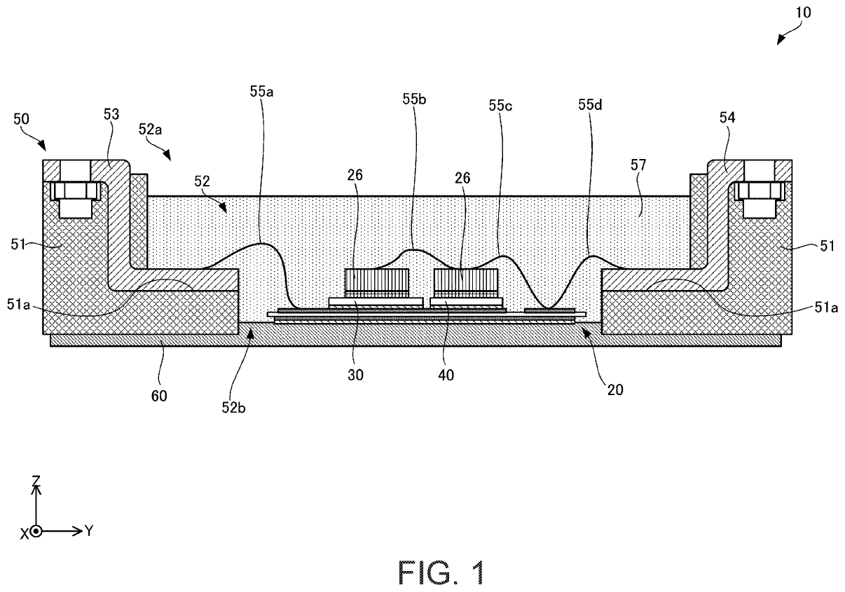

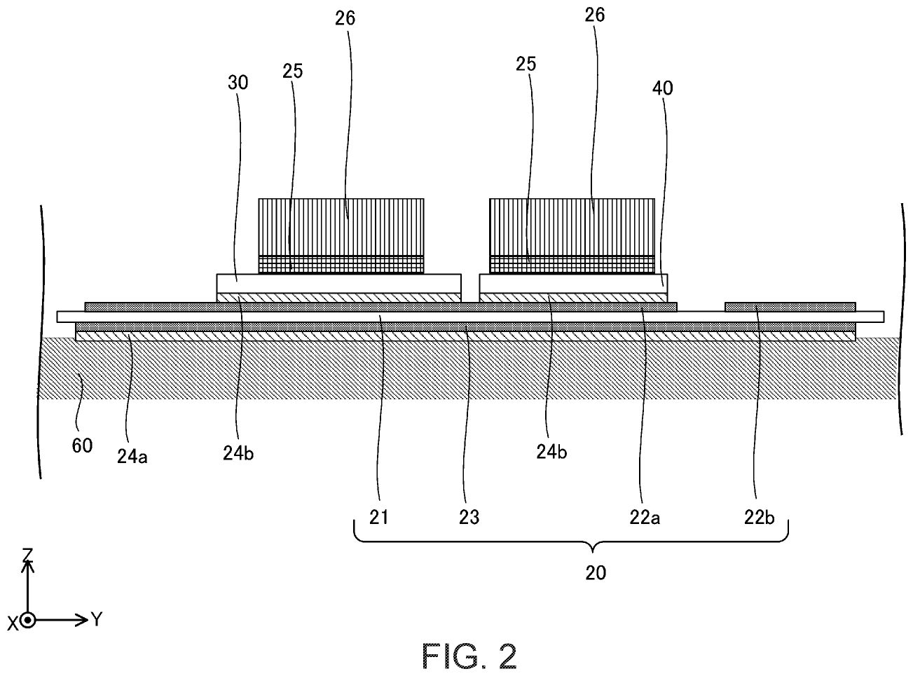

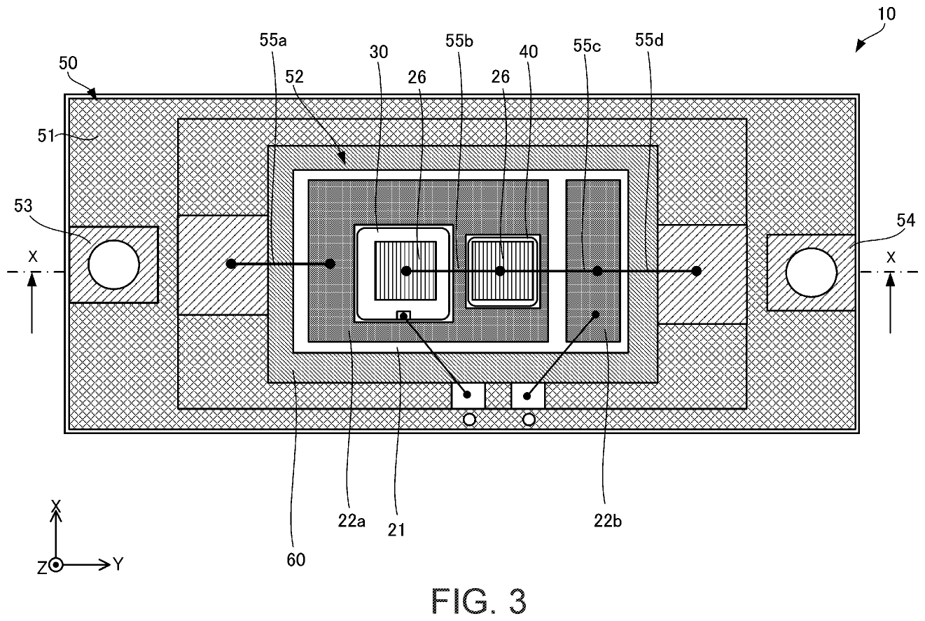

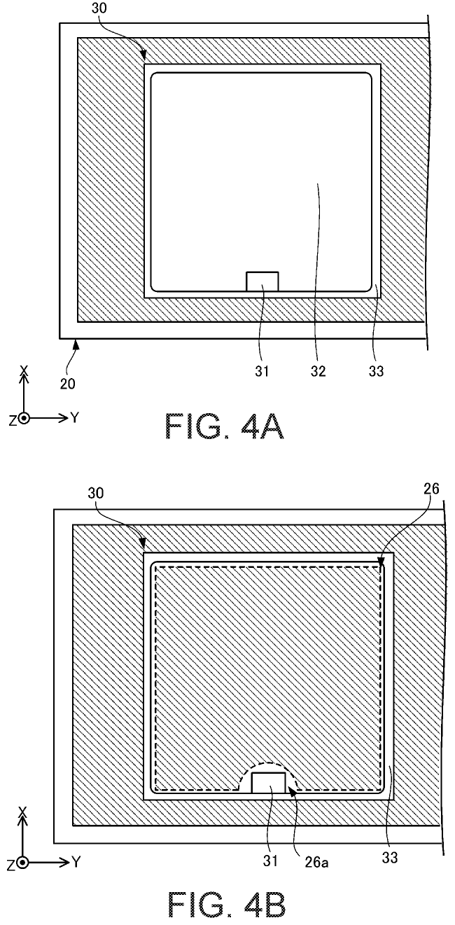

The semiconductor device of embodiments will be described with reference to FIGS. 1 to 7B. FIG. 1 is a sectional view of the semiconductor device according to an embodiment, FIG. 2 is an enlarged sectional view of a main part of the semiconductor device of the embodiment, and FIG. 3 is a plan view of the semiconductor device of the embodiment. FIGS. 4A to 7B are diagrams for explaining a heat radiating member arranged in the semiconductor chip according to various embodiments.

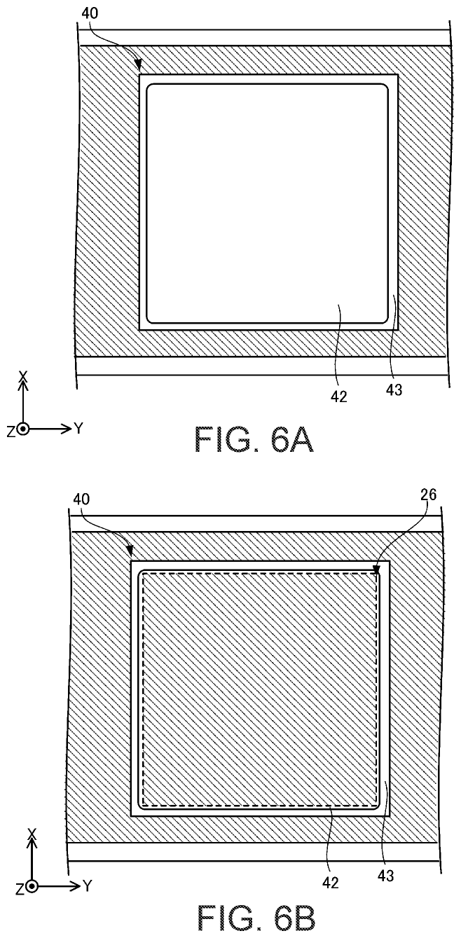

Note that FIG. 1 is a cross-sectional view taken along the alternate long and short dash line X-X of FIG. 3. FIG. 2 is an enlarged view of a region including an insulating circuit board 20 of FIG. 1. Further, FIG. 3 shows a plan view of a main part of FIG. 1 on the −Y direction side. In FIG. 3, the depiction of a sealing member 57 is omitted. FIGS. 4A to 7B are enlarged views of semiconductor chips 30 and 40 in a plan view. FIGS. 4A, 6 A, and 7A show semiconductor chips 30 and 40 with the heat radiating members 26 not arranged thereon. FIGS. 4B, 5, 6B, and 7B show semiconductor chips 30 and 40 with the heat radiating members 26 arranged thereon.

The semiconductor device 10 shown in FIGS. 1 to 3 includes an insulating circuit board 20, semiconductor chips 30, 40, a base substrate 60, a case 50, and a sealing member 57. A heat radiating member 26 is provided on the front surface of each of the semiconductor chips 30 and 40.

The insulating circuit board 20 includes an insulating plate 21, circuit patterns 22a and 22b provided on the front surface of the insulating plate 21, and a metal plate 23 provided on the back surface of the insulating plate 21. The insulating plate 21 and the metal plate 23 have a rectangular shape in a plan view. The corners of the insulating plate 21 and the metal plate 23 may be chamfered into an R shape or a C shape. The area of the metal plate 23 is smaller than the area of the insulating plate 21 in a plan view, and is formed at the inner side of the insulating plate 21.

The insulating plate 21 is made of a material having insulating properties and excellent thermal conductivity. Such an insulating plate 21 is made of ceramics or an insulating resin. The ceramics are, for example, aluminum oxide, aluminum nitride, and silicon nitride. The insulating resin is, for example, a paper phenol substrate, a paper epoxy substrate, a glass composite substrate, or a glass epoxy substrate.

The circuit patterns 22a and 22b are conductive plates made of a metal having excellent electrical conductivity. Such a metal is, for example, copper, aluminum, or an alloy containing at least one of these as a main component. The surfaces of the circuit patterns 22a and 22b may be plated in order to improve the corrosion resistance. The plating material used for the plating is, for example, nickel, nickel-phosphorus alloy, nickel-boron alloy. The circuit patterns 22a and 22b shown in FIGS. 1 to 3 are mere examples. The number, shape, size, etc., of the circuit patterns 22a and 22b can be appropriately selected.

The metal plate 23 has a rectangular shape like the insulating plate 21. The corners of the metal plate 23 may be R-chamfered or C-chamfered. The metal plate 23 is formed on the entire surface excluding the edge portion of the insulating plate 21. Such a metal plate 23 is composed mainly of a metal having excellent thermal conductivity. Such a metal is, for example, copper, aluminum, or an alloy containing at least one of these. The surface of the metal plate 23 may be plated to improve corrosion resistance. The plating material used for the plating is, for example, nickel, nickel-phosphorus alloy, nickel-boron alloy.

As the insulating circuit board 20 having such a configuration, for example, a DCB (Direct Copper Bonding) board, an AMB (Active Metal Brazed) board, or a resin insulating board can be used.

The semiconductor chips 30 and 40 each include a power device element composed mainly of a semiconductor material, for example. Such a semiconductor material is, for example, silicon, silicon carbide, or gallium nitride. The power device element is a switching element or a diode element.

In this embodiment, the semiconductor chip 30 includes a switching element. The switching element is, for example, an IGBT or a power MOSFET. As shown in FIG. 4A, such a semiconductor chip 30 has a drain electrode (or collector electrode) (i.e., a type of input electrode) as a main electrode on the back surface thereof, has a control electrode 31, as a gate electrode, in the outer peripheral portion 33 of the front surface thereof, and has another main electrode 32, as a source electrode (or an emitter electrode) (a type of input electrode) on the front surface.

In this embodiment, the semiconductor chip 40 includes a diode element. The diode element is, for example, an FWD (Free Wheeling Diode) such as an SBD (Schottky Barrier Diode) or a PiN (P-intrinsic-N) diode. As shown in FIG. 6A, such a semiconductor chip 40 is provided with a cathode electrode (a type of output electrode) as a main electrode on the back surface thereof and an anode electrode (a type of input electrode) as another main electrode 42 on the front surface thereof.

The back surfaces of the semiconductor chips 30 and 40 are directly (mechanically and electrically) bonded to the circuit pattern 22a by the joining member 24b. The joining member 24b is a solder or a metal sintered body. Lead-free solder is used as the solder. The lead-free solder contains, for example, an alloy containing at least two of tin, silver, copper, zinc, antimony, indium, and bismuth as a main component, for example. The solder may contain additives, which are, for example, nickel, germanium, cobalt or silicon. Since the solder contains additives, the wettability, gloss, and bond strength are improved, and the reliability can be improved. The metal that can be used in the metal sintered body is, for example, silver and a silver alloy.

Instead of the semiconductor chips 30 and 40, RC (Reverse-Conducting) -IGBT having both functions of IGBT and FWD may be used. Further, depending on the needs, instead of the semiconductor chips 30 and 40, or together with the semiconductor chips 30 and 40, a lead frame, an external connection terminal (pin terminal, contact component, etc.), and an electronic component (thermistor, current sensor), for example, may be arranged. Furthermore, in this embodiment, as shown in FIGS. 1, and 2, two semiconductor chips 30 and 40 are arranged on the insulating circuit board 20 as a single set. But this configuration is merely one example, and the present invention is not limited to this particular configuration. That is, two or more of such a set may be arranged depending on the design and specifications.

A heat radiating member 26 is provided on the main electrode on the front surface of each of the semiconductor chips 30 and 40 via a conductive adhesive 25. The heat radiating member 26 is mainly composed of a metal having excellent thermal conductivity. Examples of such metals include aluminum, iron, silver, copper, or alloys containing at least one of these. An example of such an alloy is a metal composite material, which may be, for example, aluminum-silicon nitride (Al—SiC) or magnesium-silicon nitride (Mg—SiC). The heat dissipation member 26 may be made of copper or aluminum, for example.

Such a heat radiating member 26 has a columnar shape. The heat radiating member 26 has a rectangular shape or a circular shape (including an elliptical shape) in a plan view. That is, the columnar shape in this case includes a prismatic columnar shape or a cylindrical shape. The area of the heat radiating member 26 in a plan view may be the same as the area of the main electrode on the front surface or smaller than the area of the main electrode. As an example, as shown in FIGS. 4B and 6B, the heat radiating member 26 may have substantially the same shape as the main electrodes 32 and 42 of the semiconductor chips 30 and 40, respectively in a plan view. The heat radiating member 26 may be arranged at the inner side of the outer peripheral portions 33 and 43 of the semiconductor chips 30 and 40. When the heat radiating member 26 has a cylindrical shape, the heat radiating member 26 in a plan view may have a size that can be arranged at the inner side of the outer peripheral portions 33, 43 of the main electrodes 32, 42 of the semiconductor chips 30, 40, respectively. In this embodiment, the case where the heat radiating member 26 has a rectangular shape in a plan view is used as an example.

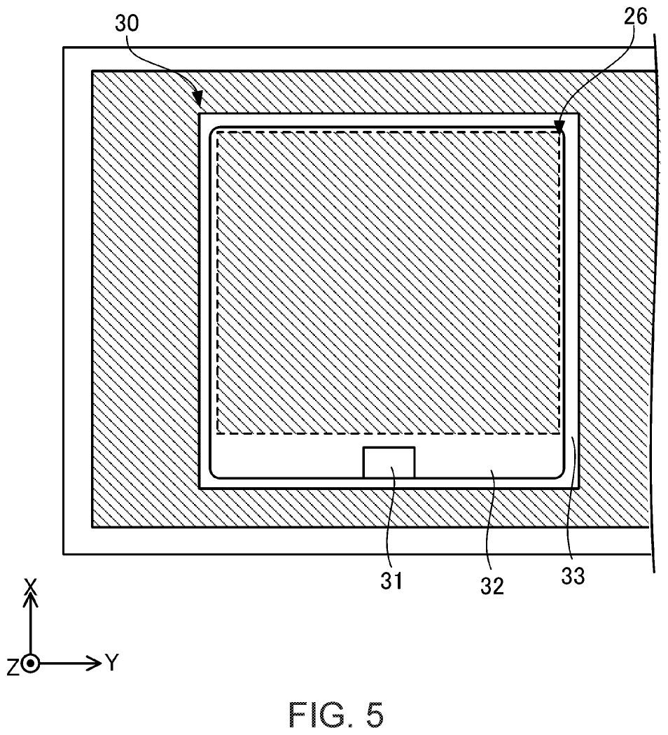

A control region 26a may be formed in the heat radiating member 26 arranged on the semiconductor chip 30 (FIG. 4B). The control region 26a is formed in a concave shape in the center of one side (−X direction) of the heat radiating member 26 in a plan view. When the heat radiating member 26 is arranged on the semiconductor chip 30, the control electrode 31 of the semiconductor chip 30 is exposed from the control region 26a. The shape of the control region 26a is not particularly limited as long as it has a concave shape in a plan view. For example, in addition to the semicircular shape as shown in FIG. 4B, a rectangular shape or a triangular shape may be used. It is desirable that the heat radiating member 26 have the largest possible contact area of the semiconductor chip 30 with respect to the main electrode 32. From this perspective, the area of the control region 26a may be the same as the area of the control electrode 31 or smaller than the area of the control electrode 31. However, the area of the control region 26a should have a sufficient size to allow wire-bonding to the control electrode 31. Furthermore, as shown in FIG. 5, the heat radiating member 26 arranged on the semiconductor chip 30 may have a shorter side length in the ±X direction. In his case, the heat radiating member 26 can be arranged on the front surface of the semiconductor chip 30 while avoiding an entire stripe-shaped region including the control electrode 31.

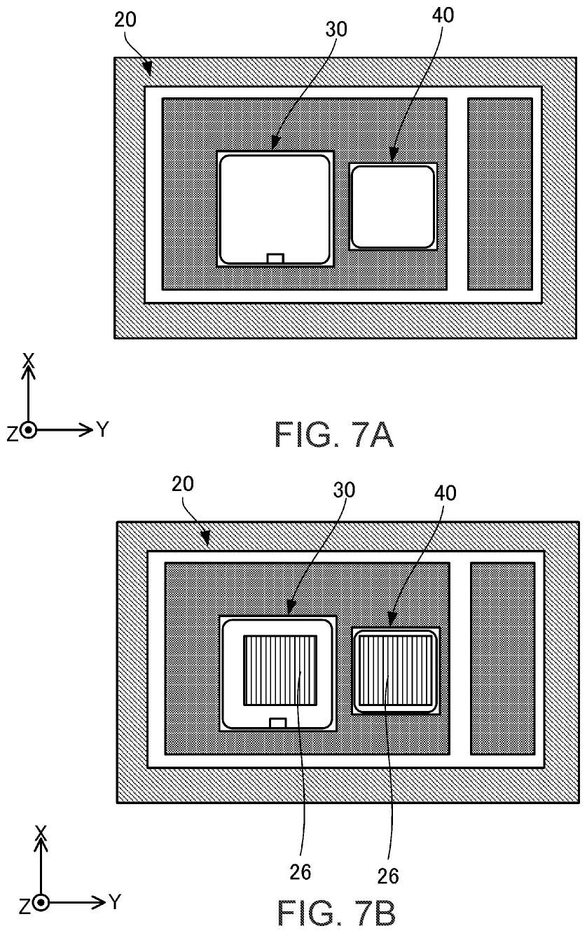

Further, the heat radiating member 26 that is used for the semiconductor chip 40 may be used for the semiconductor chip 30 as it is, as shown in FIG. 7B. The area of the front surface of the semiconductor chip 40 is smaller than the area of the front surface of the semiconductor chip 30. Utilizing this fact, the same heat radiating member 26 designed for and arranged on the semiconductor chip 40 can also be used for the semiconductor chip 30. This way, it is not necessary to prepare the heat radiating member 26 separately for each of the semiconductor chips 30 and 40, and it is possible to avoid an increase in workability and cost.

If the heat radiating member 26 is too thick, the handleability and workability of the heat radiating member 26 will deteriorate. If the heat radiating member 26 is too thin, sufficient heat radiating property cannot be obtained. Therefore, the thickness of the heat radiating member 26 is preferably 0.5 mm or more and 1.5 mm or less. Each corner and each side of the heat radiating member 26 may be R-chamfered or C-chamfered. The upper and lower surfaces of the heat radiating member 26 are substantially parallel to each other. However, the present invention is not limited to this. As will be described later, the upper surface (i.e., front surface) of the heat radiating member 26 may be joined with wires and it is sufficient if it has an area with a surface substantially parallel to the lower surface. The upper surface of the heat radiating member 26 may have, for example, a step or an uneven surface.

The conductive adhesive 25 has a sufficient heat resistance, a sufficiently low (electrical) resistance value, and a sufficiently high thermal conductivity in addition to sufficient adhesiveness. The conductive adhesive 25 should preferably maintain its adhesiveness after 300 cycles or more in a heat cycle test at −55° C. to 150° C. The resistance value is preferably 1.5×10⁻² Ω·m or less. The thermal conductivity is preferably 5 W/m·k or more. Such a conductive adhesive 25 may be made of a resin containing a conductive filler. Such a resin is, for example, a phenolic resin. The conductive filler here may be, for example, multi-walled carbon nanotubes. The multi-walled carbon nanotubes are catalytically graphitized using boron. This improves the crystallinity and conductivity of the multi-walled carbon nanotubes. Further, a dispersion aid for improving the dispersibility of the conductive filler may be added to the resin. The thickness of the conductive adhesive 25 is preferably 40 μm or more and 100 μm or less, for example. When the heat radiating member 26 is arranged on the main electrodes 32 and 42 of the semiconductor chips 30 and 40, such a conductive adhesive 25 is provided therebetween. The main electrodes 32 and 42 are made of metal (for example, aluminum).

It is conceivable to arrange the heat radiating member 26 by using, for example, solder without using the conductive adhesive 25 on the main electrodes 32 and 42. In this case, in order to improve the wettability of the main electrodes 32 and 42 with respect to the solder, it would be necessary to perform a plating treatment using nickel as a plating material on the main electrodes 32 and 42. When the conductive adhesive 25 is used, it is not necessary to perform plating on the main electrodes 32 and 42. The conductive adhesive 25 is provided directly on the main electrodes 32 and 42. By using the conductive adhesive 25 instead of a joining member such as solder, the plating process is not required and the manufacturing cost can be reduced.

The base substrate 60 has a flat plate shape and a rectangular shape in a plan view. The base substrate 60 may have a rectangular shape wider than the case 50 described later in a plan view. Such a base substrate 60 is composed mainly of a metal having excellent thermal conductivity. Examples of such metals include aluminum, iron, silver, copper, or alloys containing at least one of these. An example of such an alloy is a metal composite material. The metal composite material is, for example, Al—SiC or Mg—SiC. The base substrate 60 may be made of copper or aluminum. The surface of the base substrate 60 may be plated to improve corrosion resistance. The plating material used for that purpose is, for example, nickel, nickel-phosphorus alloy, nickel-boron alloy. The insulating circuit board 20 is bonded to the substantially central portion of the base substrate 60 by the joining member 24a. The joining member 24a here may be the above-mentioned solder or the above-mentioned metal sintered body. The joining member 24a may be made of the same material as the joining member 24b, or may be made of a different material.

Further, a cooling unit (not shown) can be attached to the back surface of the base substrate 60 (semiconductor device 10) via a heat conductive member. The heat conductive member is a thermal interface material (TIM). TIM is a general term for various materials such as thermally conductive grease, elastomer sheet, RTV (Room Temperature Vulcanization) rubber, gel, phase change material, solder, and silver wax. This structure makes it possible to improve the heat dissipation of the semiconductor device 10. The cooling unit in this case is made of, for example, a metal having excellent thermal conductivity. Such a metal is aluminum, iron, silver, copper, or an alloy containing at least one of these. Further, the cooling unit may be a heat sink having one or more fins or a water-cooled cooling device. Further, the base substrate 60 may be integrated with such a cooling unit.

The case 50 includes a frame portion 51 and lead frames 53 and 54. Step portions 51a are formed on the inner walls of the frame portions 51 facing each other (in the ±Y direction). The step portion 51a projects perpendicularly from the facing inner wall towards the housing area 52. The step portion 51a has a main surface facing in the +Z direction. In the housing area 52, the upper opening 52a communicates with the lower opening 52b. The upper opening 52a is surrounded on all sides by the inner walls of the frame 51. The lower opening 52b is surrounded on all sides by the inner walls of the frame 51 and the stepped portion 51a. Therefore, the opening area of the lower opening 52b is smaller than the opening area of the upper opening 52a.

The lead frames 53 and 54 are integrally molded with the frame portion 51, and each include an inner end portion and an outer end portion. The inner end portion is exposed from the stepped portion 51a of the frame portion 51. The outer end portion is exposed on the front surface of the frame portion 51. The portion of the lead frames 53 and 54 inside the frame portion 51 is connected to the inner end portion and the outer end portion in a cross-sectional view, and has an L shape. The lead frames 53 and 54 are conductive plates made of a metal having excellent conductivity. Such a metal is, for example, copper, aluminum, or an alloy containing at least one of these as a main component. The surfaces of the lead frames 53 and 54 may be plated to improve corrosion resistance. The plating material used for that purpose is, for example, nickel, nickel-phosphorus alloy, nickel-boron alloy. Each corner and each side of the lead frames 53 and 54 may be R-chamfered or C-chamfered.

The frame portion 51 is mainly composed of a thermoplastic resin containing a filler. Examples of such a thermoplastic resin include polyphenylene sulfide resin, polybutylene terephthalate resin, and polyamide resin. Examples of the filler include glass fiber, glass beads, calcium carbide, talc, magnesium oxide, and aluminum hydroxide. To manufacture the case 50, first, the lead frames 53 and 54 are set in a predetermined mold. Next, the mold is filled with a thermoplastic resin and heated to solidify. When the mold is removed, the case 50 is obtained. Therefore, the lead frames 53 and 54 are integrally molded with the frame portion 51.

The above-described case 50 is attached to the base board 60. An adhesive (not shown) is interposed on the back surface of the case 50 (frame portion 51) or the outer peripheral portion of the base substrate 60. The insulating circuit board 20 on the base board 60 is surrounded by a stepped portion 51a of the case 50 (frame portion 51) and an inner wall.

On the insulating circuit board 20 and the semiconductor chips 30 and 40 surrounded by the case 50, wires 55a, 55b, 55c and 55d, which are external lead-out members (lead wires), are wire-bonded as follows. The inner end of the lead frame 53 and the circuit pattern 22a of the insulating circuit board 20 are directly connected to each other by the wire 55a. The heat radiating member 26 of the semiconductor chip 30 and the heat radiating member 26 of the semiconductor chip 40 are directly connected to each other by the wire 55b. The heat radiating member 26 of the semiconductor chip 40 and the circuit pattern 22b of the insulating circuit board 20 are directly connected to each other by the wire 55c. The circuit pattern 22b of the insulating circuit board 20 and the inner end portion of the lead frame 54 are directly connected to each other by the wire 55d. A wire is connected to the control electrode 31 of the semiconductor chip 30. The wires 55a, 55b, 55c, 55d are mainly composed of a metal having excellent conductivity. Such metals are composed of aluminum, copper, or alloys containing at least one of these.

The sealing member 57 seals the housing area 52 of the case 50. The sealing member 57 seals the insulating circuit board 20, the semiconductor chips 30, 40, the wires 55a, 55b, 55c, 55d and the inner end portions of the lead frames 53, 54 on the base substrate 60. The sealing member 57 only needs to be able to seal at least these, and it is not necessary to seal up to the upper limit of the housing area 52.

The sealing member 57 contains, for example, a thermosetting resin and a filler. The thermosetting resin is, for example, an epoxy-based resin, a phenol-based resin, or a maleimide-based resin. An example of such a sealing member 57 is an epoxy resin containing a filler. Inorganic substances may be used as the filler. Examples of inorganic substances are silicon oxide, aluminum oxide, boron nitride and aluminum nitride. The sealing member 57 may be a silicone gel instead of the above-mentioned material.

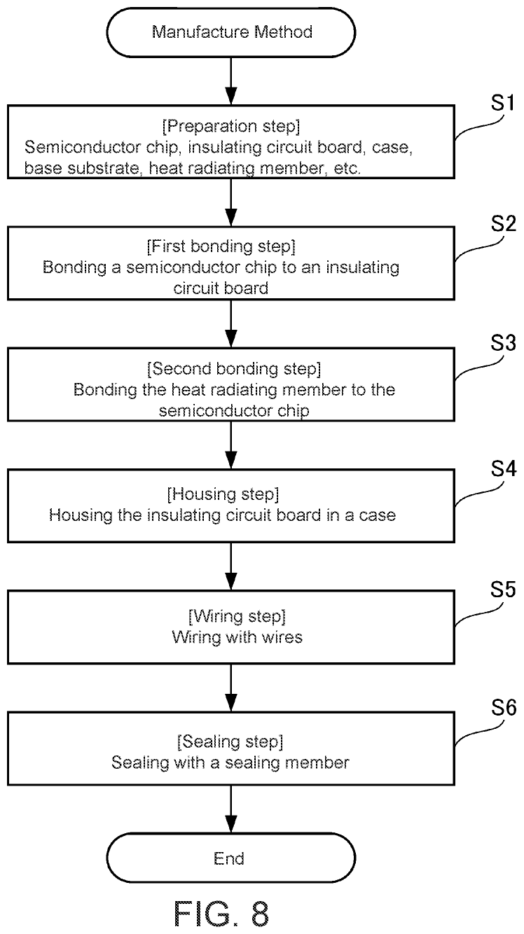

Next, the manufacturing method of the semiconductor device 10 will be described with reference to FIG. 8. FIG. 8 is a flowchart showing a method of manufacturing the semiconductor device according to an embodiment. First, a preparation process for preparing the components of the semiconductor device 10 is performed (step S1). The semiconductor chips 30, 40, the insulating circuit board 20, the case 50, the base board 60, the heat radiating member 26, and the like that will constitute the semiconductor device 10 are prepared. At this time, the conductive adhesive 25 and the sealing member 57 are also prepared.

Next, a first bonding step of bonding the semiconductor chips 30 and 40 to the insulating circuit board 20 is performed (step S2). The semiconductor chips 30 and 40 are bonded to predetermined regions of the circuit pattern 22a of the insulating circuit board 20 via the joining member 24b, respectively. At that time, the insulating circuit board 20 is also bonded to a predetermined region of the base substrate 60 via the joining member 24a. Here, the insulating circuit board 20 may be arranged on the base substrate 60 via a solder plate, and the semiconductor chips 30 and 40 may be arranged on the circuit pattern 22a of the insulated circuit board 20 via a solder plate, and heat may be applied so as to bond these elements.

Next, a second bonding step of bonding the heat radiating members 26 to each of the main electrodes 32 and 42 of the semiconductor chips 30 and 40 is performed (step S3). The conductive adhesive 25 is sprayed and applied to the main electrodes 32 and 42 of the semiconductor chips 30 and 40, for example, by a jet dispenser. The heat radiating member 26 is bonded to each of the main electrodes 32 and 42 of the semiconductor chips 30 and 40 via the conductive adhesive 25 by using a mounter, for example.

Next, a housing step of housing the insulating circuit board 20 in the case 50 is performed (step S4). The base substrate 60 to which the insulating circuit board 20 has been bonded is attached to the frame portion 51 of the case 50 from the lower opening 52b side. The base substrate 60 is bonded to the frame portion 51 with an adhesive (not shown). As a result, the insulating circuit board 20 is housed in the housing area 52 of the frame portion 51. Note that step S4 may be performed after step S2, and after performing step S4, step S3 may be performed. That is, after step S2, the insulating circuit board 20 may be housed in the case 50. After that, the heat radiating member 26 may be joined to each of the main electrodes 32 and 42 of the semiconductor chips 30 and 40.

Next, a wiring process of wiring with wires in the case 50 is performed (step S5). The insulating circuit board 20 (circuit patterns 22a and 22b), the heat dissipation members 26 and the control electrode 31 and the main electrodes 32 and 42 of the semiconductor chips 30 and 40, and the lead frames 53 and 54 in the case 50 are wired by wires such as wires (lead wires) 55a, 55b, 55c, 55d.

Next, a sealing step of sealing the inside of the housing area 52 of the case 50 with the sealing member 57 is performed (step S6). The housing area 52 of the case 50 is filled with the sealing member 57 from the upper opening 52a. As a result, the insulating circuit board 20, the semiconductor chips 30, 40, the heat radiating members 26, and the wires 55a, 55b, 55c, 55d on the base substrate 60 in the housing area 52 are sealed. When the sealing member 57 is solidified, the semiconductor device 10 shown in FIGS. 1 to 3 is completed.

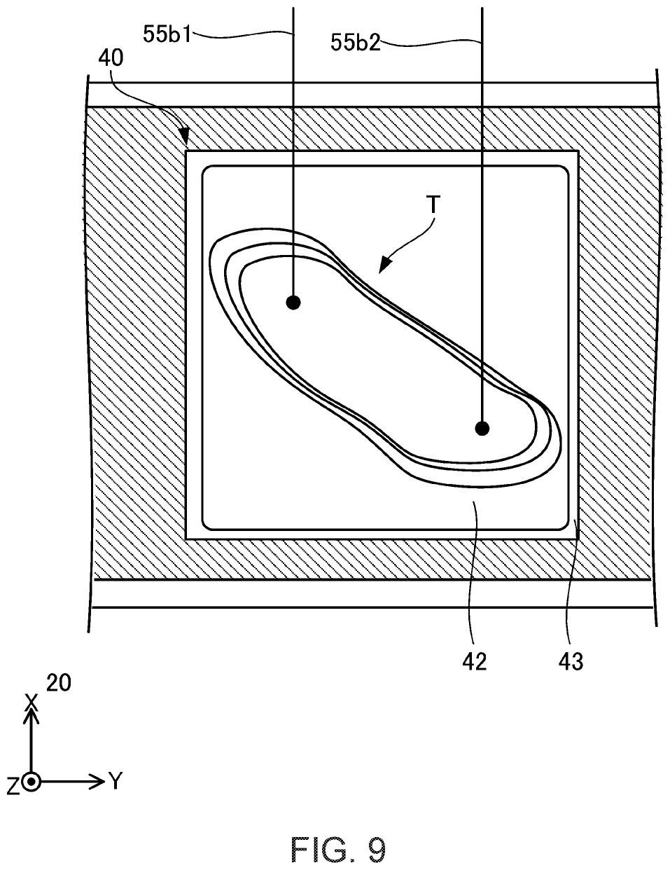

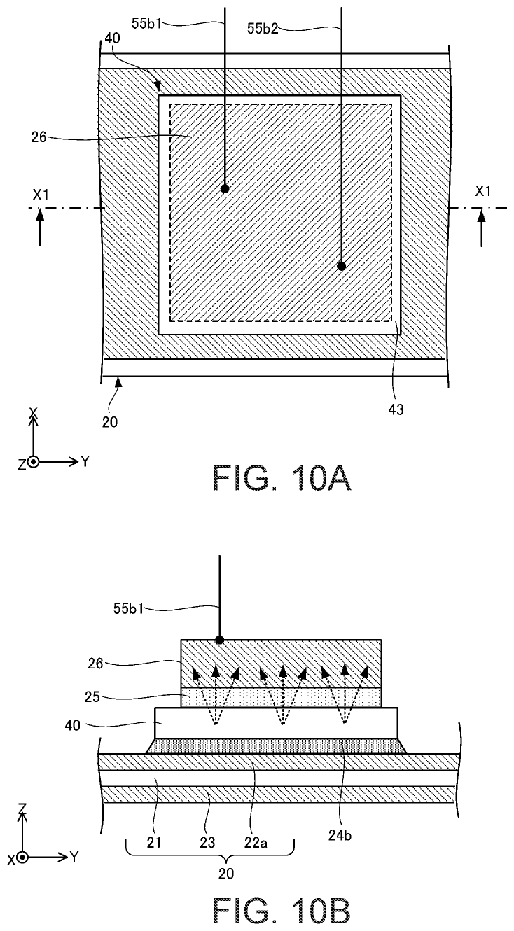

The operation of the semiconductor device 10 will be described with reference to FIGS. 9 and 10A-10B. FIG. 9 is a diagram for explaining a semiconductor chip of a reference example, and FIGS. 10A-10B are diagrams for explaining the heat radiating member arranged in the semiconductor chip of the embodiment. Here, the semiconductor chip 40 during operation of the semiconductor device 10 will be described. But, the effects are not limited to the semiconductor chip 40; the heat radiating member 26 and the conductive adhesive 25 on the semiconductor chip 30 have the same or similar effects for the semiconductor chip 30. FIGS. 9 and 10A-B show a case where two wires 55b1 and 55b2 are joined to the main electrode 42 of the semiconductor chip 40. In FIGS. 9 and 10, only the periphery of the semiconductor chip 40 above the insulating circuit board 20 is shown. FIG. 9 shows a case where the heat radiating member 26 is not provided. The contour lines T in FIG. 9 represent the temperature gradient in the main electrode 42 around the wires 55b1 and 55b2. The temperature is highest in the central region of the counter lines T and decreases toward the outside. FIG. 10B is a cross-sectional view taken along the alternate long and short dash line X1-X1 of FIG. 10A. The broken line arrows in FIG. 10B indicate the heat transfer directions.

The case where the heat radiating member 26 is not provided in the semiconductor device 10 will be described with reference to FIG. 9. When the semiconductor device 10 is directly connected to the positive electrode and the negative electrode and a control voltage is applied to the control electrode 31 of the semiconductor chip 30 at a predetermined timing, a current is input to the wires 55b1 and 55b2 and to the main electrode 42 of the semiconductor chip 40. As a result, the wires 55b1 and 55b2 are heated. In particular, when an abnormality occurs in the power conversion device on which the semiconductor device 10 is mounted, resulting in a large current flowing out from the main electrode 42 of the semiconductor chip 40 in a short period of time, the heat generation in the wires 55b1 and 55b2 also increases. When the wires 55b1 and 55b2 are heated, as shown in FIG. 9, the temperature of the regions adjacent to the wires 55b1 and 55b2 of the main electrode 42 rises. On the other hand, there is no change in temperature other than the adjacent regions of the wires 55b1 and 55b2. That is, variations in heat dispersion occur in the main electrode 42. Therefore, the wires 55b1, 55b2 may be peeled off from the main electrode 42, or the wires 55b1, 55b2 may be broken.

The case where the heat radiating member 26 is provided in the semiconductor device 10 will be described with reference to FIGS. 10A-10B. In this case, the heat radiating member 26 is arranged on the main electrode 42 of the semiconductor chip 40 via the conductive adhesive 25, and wires 55b1 and 55b2 are bonded to the front surface (i.e., the top surface) of the heat radiating member 26.

When the semiconductor device 10 operates, a current is input to the main electrode 42 of the semiconductor chip 40 from the wires 55b1 and 55b2. Further, if an abnormality occurs in the power conversion device on which the semiconductor device 10 is mounted, and a large current flows out from the main electrode 42 of the semiconductor chip 40 in a short period of time. As a result, the main electrode 42 of the semiconductor chip 40 is heated. The heat of the main electrode 42 propagates through the conductive adhesive 25 and reaches the heat radiating member 26. As shown in FIG. 10B, the heat that reaches the heat radiating member 26 is transferred to the heat radiating member 26 while being dispersed throughout the heat radiating member 26. Thus, the heat radiating member 26 is heated relatively uniformly as a whole without variation in heat dispersion. Therefore, the temperature around the wires 55b1 and 55b2 does not rise locally, which prevents the wires 55b1 and 55b2 from being separated from the heat radiating member 26 or broken.

Further, the conductive adhesive 25 has an appropriate heat resistance, an appropriate (electrical) resistance value, and an appropriate thermal conductivity in addition to sufficient adhesiveness. Therefore, even if the semiconductor chip 40 is heated, the bonding between the main electrode 42 of the semiconductor chip 40 and the heat radiating member 26 can be maintained. As a result, the heat from the main electrode 42 of the semiconductor chip 40 can also be effectively conducted to the heat dissipation member 26, and the output current output from the main electrode 42 of the semiconductor chip 40 can also be sufficiently passed onto the heat radiating member 26 and the wires 55b1 and 55b2 without impairing it.

The semiconductor device 10 includes a circuit pattern 22a, semiconductor chips 30 and 40 that have main electrodes 32 and 42, respectively, on the respective front surfaces, and main electrodes on the back surface, respectively, which are bonded to the circuit pattern 22, and the heat radiating member 26 that is provided on each of the main electrodes 32 and 42 of the semiconductor chips 30 and 40 via a conductive adhesive 25. As a result, the temperature gradient on the front surface of the heat radiating member 26 is mitigated or eliminated, and the temperature becomes substantially uniform. Moreover, the occurrence of peeling and breakage of the wires 55b1 and 55b2 bonded to the front surface of the heat radiating member 26 is suppressed. Therefore, it is possible to suppress a decrease in reliability of the semiconductor device 10.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising:
an electrically conductive plate;
a semiconductor chip on the electrically conductive plate, the semiconductor chip having a front main electrode on a front surface thereof and a back main electrode on a back surface thereof, the back main electrode being bonded to the electrically conductive plate; and
a heat radiating member that is bonded to the front main electrode via a conductive adhesive.

2. The semiconductor device according to claim 1, wherein the conductive adhesive is in direct contact with the front main electrode of the semiconductor chip.

3. The semiconductor device according to claim 1, wherein the front main electrode is made of aluminum.

4. The semiconductor device according to claim 1, further comprising a lead wire bonded to a front surface of the heat radiating member.

5. The semiconductor device according to claim 1, wherein the semiconductor chip includes a switching element, and the front main electrode is an output electrode of the switching element, and the back main electrode is an input electrode of the switching element, the semiconductor chip further including a control electrode on the front surface thereof.

6. The semiconductor device according to claim 5,
wherein the front main electrode is provided on a substantially entirety of the front surface of the semiconductor chip except for an outer peripheral portion of the front surface, and
wherein the control electrode is provided in the outer peripheral portion of the front surface.

7. The semiconductor device according to claim 6, wherein the heat radiating member is provided on the front main electrode on a substantially entirety of the front surface of the semiconductor chip except for the outer peripheral portion and a region where the control electrode is provided.

8. The semiconductor device according to claim 7, wherein the conductive adhesive is provided in a substantially entire region of the front surface where the heat radiating member is provided.

9. The semiconductor device according to claim 1, wherein the semiconductor chip includes a diode element, and the front main electrode is an input electrode of the diode element, and the back main electrode is an ouput electrode of the diode element.

10. The semiconductor device according to claim 9, wherein the front main electrode is provided on a substantially entirety of the front surface of the semiconductor chip except for an outer peripheral portion of the front surface.

11. The semiconductor device according to claim 10, wherein the heat radiating member is provided on the front main electrode on a substantially entirety of the front surface of the semiconductor chip except for the outer peripheral portion.

12. The semiconductor device according to claim 1, further comprising:
another semiconductor chip on the electrically conductive plate, the another semiconductor chip having a front main electrode on a front surface thereof and a back main electrode on a back surface thereof, the back main electrode being bonded to the electrically conductive plate, an area of the front surface of the another semiconductor chip being larger than an area of the front surface of the semiconductor chip; and
another heat radiating member that is bonded to the front main electrode of the another semiconductor chip via a conductive adhesive, an area of the another heat radiating member on the front main electrode of the another semiconductor chip being the same as an area of the heat radiating member on the front main electrode of the semiconductor chip.

13. The semiconductor device according to claim 1, wherein a resistance value of the conductive adhesive is 1.5×10⁻² Ω·m or less.

14. The semiconductor device according to claim 1, wherein a thermal conductivity of the conductive adhesive is 5 W/m·k or more.

15. A method for manufacturing a semiconductor device, comprising:
a preparation process of preparing an electrically conductive plate, a semiconductor chip having a front main electrode on a front surface thereof and a back main electrode on a back surface thereof, and a heat radiating member;
a first bonding step of bonding the back main electrode on the electrically conductive plate so as to mount the semiconductor chip on the electrically conductive plate; and
a second bonding step of bonding the heat radiating member to the front main electrode of the semiconductor chip via a conductive adhesive.

16. The method according to claim 15, wherein the conductive adhesive is in direct contact with the front main electrode of the semiconductor chip.

17. The method according to claim 15, wherein the front main electrode is made of aluminum.

18. A semiconductor device, comprising:
an electrically conductive plate;
a diode chip that includes a semiconductor diode element on the electrically conductive plate, the diode chip having a front main electrode on a front surface thereof and a back main electrode on a back surface thereof, the back main electrode being bonded to the electrically conductive plate, the front main electrode occupying a substantially entirety of the front surface except for an outer peripheral portion of the front surface;
an electrically conductive heat radiating member that is bonded to the front main electrode of the diode chip via an electrically and thermally conductive adhesive, the electrically conductive heat radiating member covering a substantially entirety of the front main electrode;
a switching element chip that includes a semiconductor switching element on the electrically conductive plate, the switching element chip having a control electrode and a front main electrode on a front surface thereof and a back main electrode on a back surface thereof, the back main electrode being bonded to the electrically conductive plate, the front main electrode occupying a substantially entirety of the front surface except for an outer peripheral portion of the front surface and a region where the control electrode is provided, an area of the front surface of the switching element chip being larger than an area of the front surface of the diode chip;
another electrically conductive heat radiating member that is bonded to the front main electrode of the switching element chip via said electrically and thermally conductive adhesive, an area of the another heat radiating member on the front main electrode of the switching element chip being greater than or the same as an area of the heat radiating member on the front main electrode of the diode chip; and
one or more of lead wires that are wire-bonded to respective front surfaces of the electrically conductive heat radiating member and the another electrically conductive heat radiating member so that the lead wires provide current paths to the diode chip and the switching element chip through the electrically conductive heat radiating member and the another electrically conductive heat radiating member, respectively,
wherein a resistance value of the electrically and thermally conductive adhesive is 1.5×10⁻² Ω·m or less, and a thermal conductivity of the electrically and thermally conductive adhesive is 5 W/m·k or more.
